(19) United States
(12) Patent Application Publication
(10) Pub. No.: US 2007/0187136 A1
(43) Pub. Date: Aug. 16, 2007

(54) Printed circuit board, method of producing the same, and electronic unit

(76) Inventors: Masahiro Higashiguchi, Hyogo (JP); Kunihiro Tan, Hyogo (JP)

Correspondence Address: COOPER & DUNHAM, LLP, 1185 AVENUE OF THE AMERICAS, NEW YORK, NY, 10036, US

(21) Appl. No.: 11/230,965

(22) Filed: Sep. 20, 2005

(30) Foreign Application Priority Data
Sep. 29, 2004 (JP) 2004-283393

(51) Int. Cl. H05K 1/00

(52) U.S. Cl. 174/250

(57) ABSTRACT

A printed circuit board is disclosed that is able to prevent outflow of a potting resin out of a sealing region. The printed circuit board includes a conductive pattern formed on an insulating substrate, an electrode for connecting an electronic part to the conductive pattern, and a stripe-like resin-outflow-prevention dam arranged in a periphery of a resin-sealing region covering the electronic part. An outer side surface and an upper surface of the resin-outflow-prevention dam subtend an acute angle.

### BACKGROUND OF THE INVENTION

1. Field of the Invention

The present invention relates to a printed circuit board including a conductive pattern formed on the surface of an insulating substrate, a mounting electrode for connecting an electronic part to the conductive pattern, and a stripe-like resin-outflow-prevention dam provided in a periphery of a resin sealing region covering the area where the electronic part is mounted to prevent outflow of resin, a method of forming the resin-outflow-prevention dam, and an electronic unit including the printed circuit board.

2. Description of the Related Art

In an electronic unit including elements such as semiconductor chips, flip chips, or resistors mounted on a printed circuit board, in order to protect these elements, they are sealed by using resin. For example, there is a simple method of sealing the elements by potting, in which liquid resin is potted onto a circuit portion for sealing.

When sealing elements on the printed circuit board by potting, if the viscosity of a potting resin is high, the resin can hardly spread, so that the height of the resin after curing is large, and this makes it difficult to reduce the thickness of the circuit and therefore not suitable for fabricating compact circuit boards. On the other hand, if the viscosity of the potting resin is low, the resin cannot be too high, but it spreads easily and covers an excessively broad region. As a solution to this problem, usually, a resin-outflow-prevention dam is provided in the periphery of a resin-sealing region on the printed circuit board to prevent outflow of the potting resin.

FIG. 7 is a cross-sectional view of an electronic unit in the related art.

In FIG. 7, on an insulating substrate, there are provided a conductive pattern 42 and a resin-outflow-prevention dam 44 for preventing outflow of a resin, forming a printed circuit board. At the center of the printed circuit board, for example, an electronic part 46 is mounted, and the electronic part 46 is electrically connected to the conductive pattern 42 through a bonding wire 48.

In the electronic unit shown in FIG. 7, potting resin 50 is applied in the periphery of a region covering the electronic part 46 to seal the electronic part 46, and the potting resin 50 is dammed by the resin-outflow-prevention dam 44 so as not to run out of the sealing region.

In the related art, various proposals have been made concerning the materials of resin-outflow-prevention dam 44 and methods of fabricating the resin-outflow-prevention dam 44 in the electronic unit shown in FIG. 7.

For example, Japanese Utility Model Application Kokoku No. 49-043873 (below, referred to as “reference 1”) discloses a structure in which a ring-shaped resin-outflow-prevention dam is formed from silicon-based resin by screen-printing, and the inner part of the resin-outflow-prevention dam is sealed by using epoxy resin.

Additionally, Japanese Laid-Open Utility Model Application No. 55-156447 (below, referred to as “reference 2”) discloses a resin-outflow-prevention dam formed from UV curable resin or X-ray curable resin.

Japanese Laid-Open Utility Model Application No. 55-025381 (below, referred to as “reference 3”) discloses a resin-outflow-prevention dam formed from a solder resist, forming a barrier having a certain height.

Japanese Laid-Open Utility Model Application No. 58-048442 (below, referred to as “reference 4”) discloses a resin-outflow-prevention dam formed by screen-printing and having a dam height from 300 to 500 μm.

Japanese Utility Model Gazette No. 2507829 (below, referred to as “reference 5”) discloses a resin-outflow-prevention dam having a width from 300 to 1200 μm and a height from 50 to 300 μm, and a cross section close to trapezoidal.

When the ring-shaped resin-outflow-prevention dam is formed from silicon-based resin, as in reference 1, even when the height of the ring-shaped resin-outflow-prevention dam is small, because of the water-repellent effect of silicon, an excellent sealing effect can be obtained; thus, even when the viscosity of the potting resin 50 is low, the resin can still be sufficiently high. However, because the water-repellent effect of silicon is very strong, the potting resin 50 cannot be applied to the end of the sealing region.

When the resin-outflow-prevention dam 44 is formed primarily from epoxy resin, because the resin-outflow-prevention dam 44 has good affinity with the potting resin 50, it is difficult to make the resin--outflow-prevention dam 44 high. Thus, in order to ensure an appropriate height of the potting resin 50, it is necessary to make the resin-outflow-prevention dam 44 higher than the potting resin 50 by a few hundreds of μm, and further increase the viscosity of the potting resin 50.

In order to increase the height of the resin-outflow-prevention dam 44, it is needed to increase the viscosity of the resin-outflow-prevention dam 44, and this makes the fabrication process complicated. Similarly, when the viscosity of the resin-outflow-prevention dam 44 is high, the fabrication process becomes complicated, too.

When the resin-outflow-prevention dam 44 is formed from UV curable resin, as in reference 2, because the resin-outflow-prevention dam 44 cures in a short time, it is easy to obtain a sufficiently large height. However, such a resin-outflow-prevention dam 44 has a weak adhesive force with the epoxy resin on the printed circuit board, and low water-resistance; thus, the process of forming the sealing frame has to be fixed.

When the resin-outflow-prevention dam 44 is formed from a solder resist, as in the reference 3, usually the thickness of the resist is about 20 μm, which is very thin, and thus, this method is not applicable to situations requiring a certain height for potting.

### SUMMARY OF THE INVENTION

It is a general object of the present invention to solve one or more problems of the related art.

A specific object of the present invention is to provide a printed circuit board able to prevent outflow of potting resin out of a sealing region when applying the potting resin, and an electronic unit including the printed circuit board.

According to a first aspect of the present invention, there is provided a printed circuit board, comprising: a conductive pattern formed on an insulating substrate; an electrode for connecting an electronic part to the conductive pattern; and a stripe-like resin-outflow-prevention dam arranged in a periphery of a resin-sealing region covering the electronic part, wherein an outer side surface of the resin-outflow-prevention dam and an upper surface of the resin-outflow-prevention dam subtend an acute angle.

According to the present invention, the outer side surface and the upper surface of the resin-outflow-prevention dam subtend an acute angle. Therefore, due to surface tension at the angular portion of the acute angle subtended by the outer side surface and the upper surface of the resin-outflow-prevention dam, the sealing resin can hardly drop from the outer side surface, and thus, it is possible to prevent the sealing resin from running out of the sealing region.

As an embodiment, the resin-outflow-prevention dam may have a quadrilateral cross-section; and a width of the upper surface of the resin-outflow-prevention dam is greater than a width of a lower surface of the resin-outflow-prevention dam. For example, the resin-outflow-prevention dam may have approximately an inverse trapezoidal cross section.

According to the present invention, because the resin-outflow-prevention dam may have a quadrilateral cross section, for example, the resin-outflow-prevention dam may have approximately an inverse trapezoidal cross section, and the width of the upper surface may be greater than the width of the lower surface, due to the surface tension at the angular portion of the acute angle subtended by the outer side surface and the upper surface of the resin-outflow-prevention dam, the sealing resin can hardly drop from the outer side surface. Thus, it is possible to prevent the sealing resin from running out of the sealing region.

Here, “approximately an inverse trapezoid” may include an incomplete inverse trapezoid, for example, those having rounded corners, or curved side surfaces caused by etching.

As an embodiment, an insulating material layer may be formed on the printed circuit board and may at least have an opening in a region where the electrode is formed, and the resin-outflow-prevention dam may be formed on the insulating material layer.

According to the present invention, because an insulating material layer may be formed on the printed circuit board and may at least have an opening in a region where the electrode is formed, and the resin-outflow-prevention dam may be formed on the insulating material layer, due to the surface tension at the angular portion of the acute angle subtended by the outer side surface and the upper surface of the resin-outflow-prevention dam, the sealing resin can hardly drop from the outer side surface. Thus, it is possible to prevent the sealing resin from running out of the sealing region.

As an embodiment, an insulating material layer may be formed on the printed circuit board and may at least have an opening in a region where the electrode is formed, and the resin-outflow-prevention dam may be formed from the insulating material.

According to the present invention, because an insulating material layer may be formed on the printed circuit board and may at least have an opening in a region where the electrode is formed, and the resin-outflow-prevention dam may be formed from the insulating material, the resin-outflow-prevention dam may be formed by removing an unnecessary portion of the insulating material layer. Hence, additional steps are not needed to form the resin-outflow-prevention dam, and this makes it easy to fabricate the resin-outflow-prevention dam.

According to a second aspect of the present invention, there is provided an electronic unit, comprising: a printed circuit board having a conductive pattern formed on an insulating substrate, an electrode, and a stripe-like resin-outflow-prevention dam; and an electronic part that is connected to the conductive pattern through the electrode so as to be mounted on the printed circuit board, wherein the resin-outflow-prevention dam is arranged in a periphery of a resin-sealing region covering the electronic part, and resin for sealing is applied in the resin-sealing region so as to cover the upper surface of the resin-outflow-prevention dam.

According to the present invention, in the electronic unit of the present invention, an electronic is connected to a conductive pattern through an electrode, and resin is applied in a resin-sealing region to cover the upper surface of the resin-outflow-prevention dam. Therefore, in the angular portion subtended by the outer side surface and the upper surface of the resin-outflow-prevention dam, the resin projects upward due to the surface tension, resulting in a sufficient height of the resin.

According to a third aspect of the present invention, there is provided a method of producing a printed circuit board including a conductive pattern formed on an insulating substrate, and an electrode for connecting an electronic part to the conductive pattern; and a resin-outflow-prevention dam arranged in a periphery of a resin-sealing region covering the electronic part. The method comprises the steps of: depositing a material layer on the insulating substrate for forming the resin-outflow-prevention dam; forming an etching mask pattern on the material layer in an area where the resin-outflow-prevention dam is to be formed; etching the material layer selectively by dry etching with the etching mask pattern as a mask to selectively remove the material layer; and over-etching the material layer to form the resin-outflow-prevention dam having approximately an inverse trapezoidal cross section.

According to the present invention, the material layer is etched selectively by dry etching with the etching mask pattern as a mask to remove the material layer selectively, and then the material layer is over-etched, thereby obtaining the resin-outflow-prevention dam having approximately an inverse trapezoidal cross section.

According to a fourth aspect of the present invention, there is provided a method of producing a printed circuit board including a conductive pattern formed on an insulating substrate, and an electrode for connecting an electronic part to the conductive pattern; and a resin-outflow-prevention dam arranged in a periphery of a resin-sealing region covering the electronic part. The method includes the steps of: depositing a positive photo-sensitive material layer on the insulating substrate for forming the resin-outflow-prevention dam; arranging a light-shielding mask on the photo-sensitive material layer in an area where the resin-outflow-prevention dam is to be formed; over-exposing the photo-sensitive material layer by using the light-shielding mask; and developing the photo-sensitive material layer to form the resin-outflow-prevention dam having approximately an inverse trapezoidal cross section.

According to the present invention, a light-shielding mask is arranged on the photo-sensitive material layer in an area where the resin-outflow-prevention dam is to be formed, and the photo-sensitive material layer is over-exposed by using the light-shielding mask, and then the photo-sensitive material layer is developed, resulting in the resin-outflow-prevention dam having approximately an inverse trapezoidal cross section.

These and other objects, features, and advantages of the present invention will become more apparent from the following detailed description of preferred embodiments given with reference to the accompanying drawings.

### BRIEF DESCRIPTION OF THE DRAWINGS

FIG. 1A is a plan view of a printed circuit board according to a first embodiment of the present invention;

FIG. 1B is a cross-sectional view of the printed circuit board in FIG. 1A along an X-X line in FIG. 1A;

FIG. 2A through FIG. 2F are cross-sectional views of a portion of the printed circuit board 1 illustrating a method of fabricating the resin-outflow-prevention dam 10 according to the first embodiment;

FIG. 3A through FIG. 3C are cross-sectional views of portions of the printed circuit board 1 illustrating another method of fabricating the resin-outflow-prevention dam 10 according to the first embodiment;

FIG. 4A is a plan view of a printed circuit board according to a second embodiment of the present invention;

FIG. 4B is a cross-sectional view of the printed circuit board in FIG. 4A along a Y-Y line in FIG. 4A;

FIG. 5A is a cross-sectional view of an electronic unit according to a third embodiment of the present invention;

FIG. 5B is an enlarged cross-sectional view of a portion of the electronic unit indicated by a dashed circle in FIG. 5A;

FIG. 6 is a view illustrating a modification of the present invention; and

FIG. 7 is a cross-sectional view of an electronic unit in the related art.

### DESCRIPTION OF THE PREFERRED EMBODIMENTS

Below, preferred embodiments of the present invention are explained with reference to the accompanying drawings.

### First Embodiment

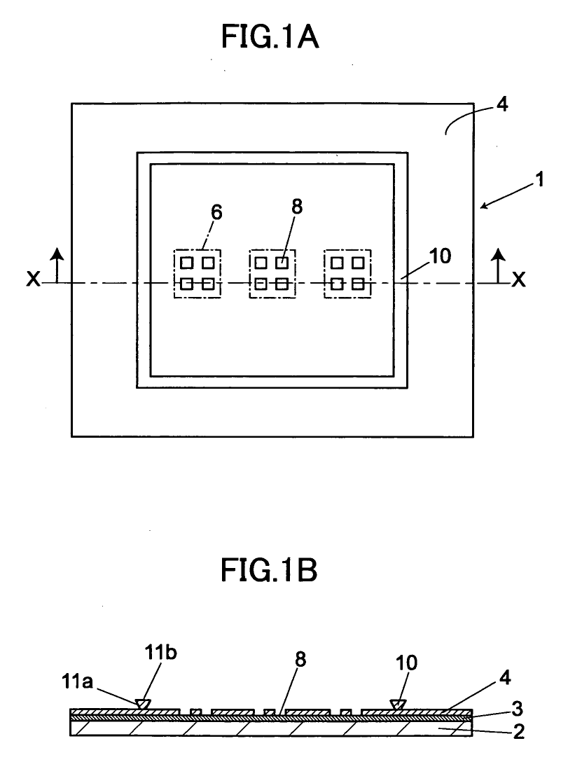

FIG. 1A is a plan view of a printed circuit board according to a first embodiment of the present invention.

FIG. 1B is a cross-sectional view of the printed circuit board in FIG. 1A along an X-X line in FIG. 1A.

As illustrated in FIG. 1A, in a printed circuit board 1, a conductive pattern 3 is formed on an insulating substrate 2 by patterning a metal layer on the insulating substrate 2, and a solder resist 4 is formed on the conductive pattern 3 as an insulating material layer. The solder resist 4 has functions of preventing degradation of the printed circuit board 1 caused by oxidation of the conductive pattern 3, and preventing a short between the solder applied when mounting electronic parts and electrodes nearby or the conductive pattern 3. For example, the solder resist 4 is made from PSR-4000 G30, manufactured by Taiyo Ink Co.

In the printed circuit board 1, for example, three mounting areas 6 are provided in the printed circuit board 1 for mounting three electronic parts (such as semiconductor devices) on the printed circuit board 1. Three groups of electrodes, each of which groups includes four electrodes 8, are formed in the three mounting areas 6, respectively, for electrically connecting the electronic parts to the conductive pattern 3. The solder resist 4 has openings corresponding to the electrodes 8, hence, the electrodes 8 are exposed.

The region covering the three mounting areas 6 is a sealing-region, where potting resin is to be applied to seal the electronic parts after the electronic parts are mounted. In the peripheral region of the sealing-region, a resin-outflow-prevention dam 10 is arranged to prevent outflow of the potting resin out of a sealing region when applying the potting resin. For example, the resin-outflow-prevention dam 10 is formed from the same material as the solder resist 4, and is on the solder resist 4.

As illustrated in FIG. 1B, an outer side surface 11a of the resin-outflow-prevention dam 10 relative to the sealing-region and the upper surface 11b of the resin-outflow-prevention dam 10 subtend an acute angle. For example, the cross section of the resin-outflow-prevention dam 10 is approximately an inverse trapezoid.

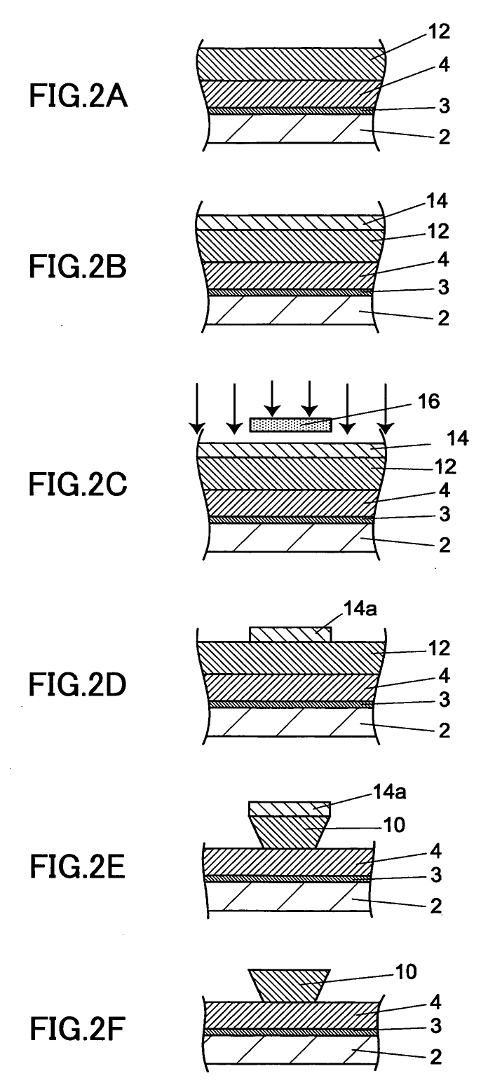

Below, a method of fabricating the resin-outflow-prevention dam 10 is described with reference to FIG. 2A through FIG. 2F.

FIG. 2A through FIG. 2F are cross-sectional views of a portion of the printed circuit board 1 illustrating a method of fabricating the resin-outflow-prevention dam 10 according to the first embodiment.

In the step shown in FIG. 2A, a solder resist 12 is applied on the solder resist 4, which is formed on the printed circuit board 1 in advance. For example, the thickness of the solder resist 12 is 20 to 30 μm, which is the typical thickness of solder resists in printed circuit boards. For example, the solder resist 12 is made from PSR-4000 G30, manufactured by Taiyo Ink Co.

In the step shown in FIG. 2B, a positive photosensitive resist 14 is deposited on the solder resist 12.

In the step shown in FIG. 2C, a photo mask 16 is arranged on the photosensitive resist 14, the photo mask 16 having a light shielding portion at a position corresponding to the area where the resin-outflow-prevention dam 10 is to be formed. The photosensitive resist 14 is exposed by using the photo mask 16.

In the step shown in FIG. 2D, the photosensitive resist 14 is developed after being exposed, and forms a resist 14a corresponding to the area where the resin-outflow-prevention dam 10 is to be formed.

In the step shown in FIG. 2E, the solder resist 12 is etched with the resist 14a as a mask to form the resin-outflow-prevention dam 10. In this etching process, the solder resist 12 is over-etched by dry etching so that the width of the surface of the resin-outflow-prevention dam 10 in contact with the resist 14a (that is, the upper surface) is greater than the width of the surface of the resin-outflow-prevention dam 10 in contact with the solder resist 4 (that is, the lower surface).

In the step shown in FIG. 2F, after the etching process, the resist 14a is removed, and the resin-outflow-prevention dam 10 is formed which has approximately an inverse trapezoidal cross section, that is, the width of the upper surface is greater than the width of the lower surface.

As described above, because the resin-outflow-prevention dam 10 is formed from the same insulating material as the solder resist 4, additional steps are not needed when forming the resin-outflow-prevention dam 10, and usual etching processing is sufficient. This makes it easy to fabricate the resin-outflow-prevention dam 10.

Although it is described that the resin-outflow-prevention dam 10 is preferably formed from a solder resist, in the present invention, the material of the resin-outflow-prevention dam 10 is not limited to the solder resist, and other materials may be used.

In addition to a method involving over-etching, the resin-outflow-prevention dam 10 may also be formed by over-exposure.

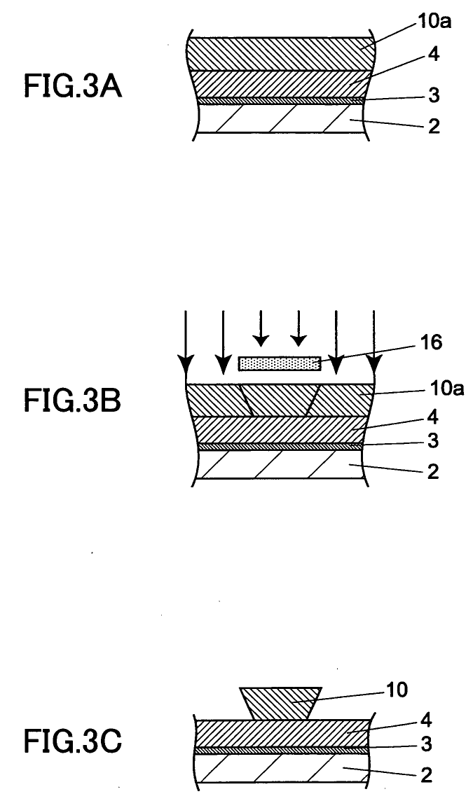

FIG. 3A through FIG. 3C are cross-sectional views of portions of the printed circuit board 1 illustrating another method of fabricating the resin-outflow-prevention dam 10 according to the first embodiment.

In the step shown in FIG. 3A, a positive solder resist 10a is applied on the solder resist 4, which is formed on the printed circuit board 1 in advance. For example, the thickness of the solder resist 10a is from 20 to 30 μm, which is the typical thickness of solder resists in printed circuit boards. For example, the solder resist 10a is made from PSR-4000 G30, manufactured by Taiyo Ink Co.

In the step shown in FIG. 3B, a photo mask 16 is arranged on the solder resist 10a. The photo mask 16 has a light shielding portion at a position corresponding to the area where the resin-outflow-prevention dam 10 is to be formed. The solder resist 10a is over-exposed by using the photo mask 16.

In the step shown in FIG. 3C, the solder resist 10a is developed after being exposed, and the resin-outflow-prevention dam 10 is formed which has approximately an inverse trapezoidal cross section. According to the present embodiment, because the outer side surface 11a of the resin-outflow-prevention dam 10 relative to the sealing region and the upper surface 11b of the resin-outflow-prevention dam 10 subtend an acute angle, when applying the resin for sealing, due to surface tension at the angular portion of the acute angle, the potting resin can hardly drop from the outer side surface 11a. Thus, it is possible to prevent the potting resin from running out of the sealing region.

When applying the resin for sealing, because the potting resin is applied to cover the upper surface 11b of the resin-outflow-prevention dam 10, even although the potting resin has low viscosity, due to the surface tension, the potting resin projects upward on the upper surface 11b of the resin-outflow-prevention dam 10, resulting in a sufficient height of the potting resin even when the resin-outflow-prevention dam 10 is low.

In the above examples, it is described that the resin-outflow-prevention dam 10 has approximately an inverse trapezoidal cross section, and the upper surface and the lower surface of the resin-outflow-prevention dam 10 are parallel to each other. Certainly, the upper surface may be inclined in the direction from the outside to the inner side of the sealing region.

In the above examples, it is described that the side surface of the resin-outflow-prevention dam 10 is inclined inward. Of course, the side surface of the resin-outflow-prevention dam 10 may also be perpendicular to the print circuit board 1, or be inclined outward.

In the above examples, it is described that the resin-outflow-prevention dam 10 has a quadrilateral cross section, but the cross section of the resin-outflow-prevention dam 10 may be other shapes. For example, the outer side surface and/or the inner side surface of the resin-outflow-prevention dam 10 may be bent, or curved.

In the above examples, it is described that the width of the upper surface of the resin-outflow-prevention prevention dam 10 is greater than the width of the lower surface of the resin-outflow-prevention dam 10, but the resin-outflow-prevention dam 10 of the present embodiment is not limited to this shape, and the width of the upper surface of the resin-outflow-prevention dam 10 may be equal to or less than the width of the lower surface of the resin-outflow-prevention dam 10.

In the above examples, it is described that three mounting areas 6 are provided, but the printed circuit board 1 of the present embodiment is not limited to this, and one, or two, or four mounting areas 6 may be provided.

In the above examples, it is described that the region covering the three mounting areas 6 is the sealing-region where potting resin is applied to seal the electronic parts after the electronic parts are mounted, but the printed circuit board 1 of the present embodiment is not limited to this. For example, the regions covering the respective mounting areas 6 can be separate sealing-regions, or the sealing-regions can be defined in any other way.

In the above examples, it is described that the mounting electrodes are formed within the mounting areas 6 for electrically connecting the electronic parts to the conductive pattern 3, but the printed circuit board 1 of the present embodiment is not limited to this. For example, the mounting electrodes may be formed outside the mounting areas 6.

### Second Embodiment

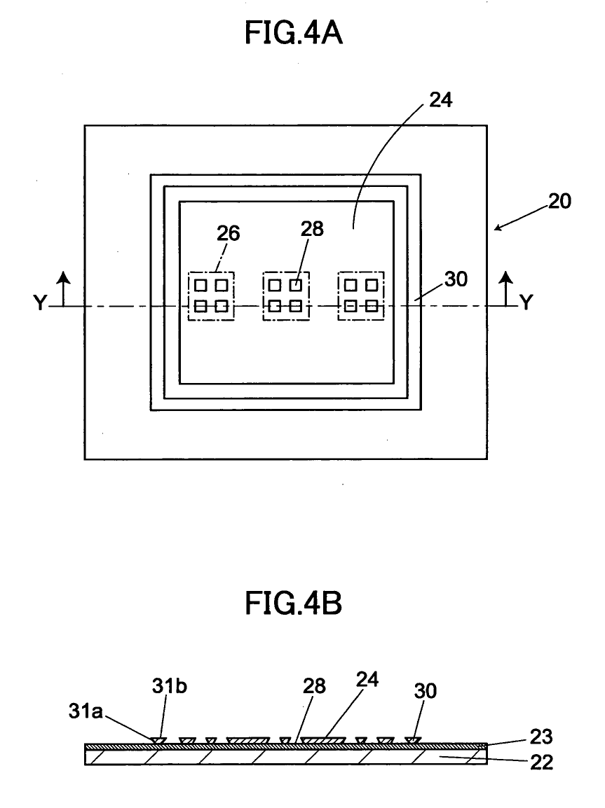

FIG. 4A is a plan view of a printed circuit board according to a second embodiment of the present invention.

FIG. 4B is a cross-sectional view of the printed circuit board in FIG. 4A along a Y-Y line in FIG. 4A.

As illustrated in FIG. 4A, in a printed circuit board 20, a conductive pattern 23 is formed on an insulating substrate 22, and a solder resist 24 is formed in the peripheral region of mounting areas 26, where electronic parts (such as, semiconductor devices) are to be mounted. The solder resist 24 has functions of preventing degradation of the printed circuit board 20 caused by oxidation of the conductive pattern 23, and preventing a short between the solder applied when mounting the electronic parts and electrodes nearby or the conductive pattern 3.

In the printed circuit board 20, for example, three mounting areas 26 are provided, and three groups of electrodes 28, each of which groups includes four electrodes 28, are formed in the three mounting areas 26, respectively, for electrically connecting the electronic parts to the conductive pattern 23. The solder resist 24 has openings corresponding to the electrodes 28, hence the electrodes 28 are exposed.

In the peripheral region of the sealing-region, a resin-outflow-prevention dam 30 is arranged to prevent outflow of the potting resin out of a sealing region when applying the potting resin. For example, the resin-outflow-prevention dam 30 is formed from the same material as the solder resist 24, and is on the conductive pattern 23.

As illustrated in FIG. 4B, an outer side surface 31a of the resin-outflow-prevention dam 30 relative to the sealing-region and the upper surface 31b of the resin-outflow-prevention dam 30 subtend an acute angle. For example, the cross section of the resin-outflow-prevention dam 30 is approximately an inverse trapezoid.

Preferably, the resin-outflow-prevention dam 30 is fabricated by over-exposure as shown in FIG. 3A through FIG. 3C, but the resin-outflow-prevention dam 30 may also be fabricated by over-etching as shown in FIG. 2A through FIG. 2F.

In the above methods, because the resin-outflow-prevention dam 30 can be fabricated at the same time when fabricating the solder resist 24, which is able to prevent degradation caused by oxidation of the conductive pattern 23, and prevent a short between the solder applied when mounting the electronic parts and the electrodes 28 nearby or the conductive pattern 23, additional steps are not needed for forming the resin-outflow-prevention dam 30, and this makes it easy to fabricate the resin-outflow-prevention dam 30.

According to the present embodiment, because the outer side surface 31a and the upper surface 31b of the resin-outflow-prevention dam 30 subtend an acute angle, and the cross section of the resin-outflow-prevention dam 30 is approximately an inverse trapezoid, when applying the resin for sealing, due to surface tension at the angular portion of the acute angle, the potting resin can hardly drop from the outer side surface 31a. Thus, it is possible to prevent the potting resin from running out of the sealing region.

When applying the resin for sealing, because the potting resin is applied to cover the upper surface 31b of the resin-outflow-prevention dam 30, even though the potting resin has low viscosity, due to the surface tension, the potting resin projects upward on the upper surface 31b of the resin-outflow-prevention dam 30, resulting in a sufficient height of the potting resin even when the resin-outflow-prevention dam 30 is low.

Similar to the first embodiment, the shape of the resin-outflow-prevention dam 30, the number and position of the mounting areas 26 and the electrodes 28, and so on are not limited to the above example, and may be changed within the scope of the present embodiment.

The region where to form the solder resist 24 can be changed within the scope of the present embodiment, and when necessary, the solder resist 24 may be omitted.

### Third Embodiment

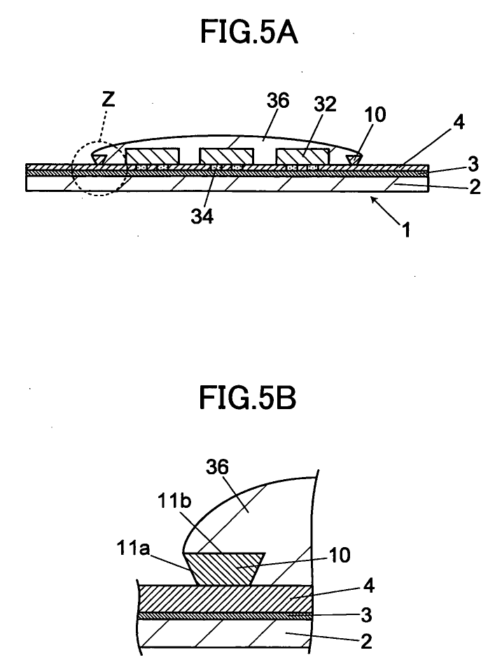

FIG. 5A is a cross-sectional view of an electronic unit according to a third embodiment of the present invention.

FIG. 5B is an enlarged cross-sectional view of a portion of the electronic unit indicated by a dashed circle in FIG. 5A.

In the following descriptions, the same reference numbers are assigned to the same elements as those described in the previous embodiments, and overlapping descriptions are omitted.

In FIG. 5A, three electronic parts 32 are mounted on the mounting areas 26 of the printed circuit board 1. For example, the electronic parts 32 are flip chip semiconductor devices, in each of which connection terminals (not illustrated) are provided on the back surface. The connection terminals on the back surface of each of the electronic parts 32 are electrically connected to the mounting electrodes 8 on the printed circuit board 1 through solder 34, and the electronic parts 32 are electrically connected to external electric devices through the conductive pattern 3.

Potting resin 36 is applied in the periphery of a sealing region, which covers the region where the electronic parts 32 are mounted, to protect the electronic parts 32.

As illustrated in FIG. 5B, the potting resin 36 spreads to the edge of the resin-outflow-prevention dam 10, and the potting resin 36 projects upward on the upper surface 11b of the resin-outflow-prevention dam 10 due to surface tension, making the potting resin 36 sufficiently high.

In the electronic unit of the present embodiment, as illustrated in FIG. 5B, the cross section of the resin-outflow-prevention dam 10 is approximately an inverse trapezoid, and the outer side surface 11a and the upper surface 11b of the resin-outflow-prevention dam 10 subtend an acute angle. When applying the resin for sealing, due to the surface tension at the angular portion of the acute angle, the potting resin can hardly drop from the outer side surface 11a, thus the potting resin is dammed within the sealing region.

When applying the potting resin 36, because the potting resin 36 is applied to cover the upper surface 11b of the resin-outflow-prevention dam 10, due to the surface tension, the potting resin 36 projects upward on the upper surface 11b of the resin-outflow-prevention dam 10, and obtains a sufficient height.

According to the present embodiment, because the outer side surface 11a and the upper surface 11b of the resin-outflow-prevention dam 10 subtend an acute angle, and the cross section of the resin-outflow-prevention dam 10 is approximately an inverse trapezoid, when applying the potting resin 36 for sealing, due to surface tension at the angular portion of the acute angle, the potting resin 36 can hardly drop from the outer side surface 11a. Thus, it is possible to prevent the potting resin 36 from running out of the sealing region.

Because the potting resin 36 is applied to cover the upper surface 11b of the resin-outflow-prevention dam 10, even though the potting resin 36 has low viscosity, due to the surface tension, the potting resin 36 projects upward on the upper surface 11b of the resin-outflow-prevention dam 10, resulting in a sufficient height of the potting resin 36 even when the resin-outflow-prevention dam 10 is low.

In the above examples, it is described that in the electronic unit, the connection terminals of the electronic parts 32 are electrically connected to the mounting electrodes 8 by using solder, but they can also be electrically connected by using bonding wires. In addition, instead of the printed circuit board 1 of the first embodiment, the printed circuit board 20 of the second embodiment may also be used in the electronic unit.

The present invention is also applicable to an electronic unit panel including plural electronic units, which are sealed on plural printed circuit boards, respectively, with all the printed circuit boards being sealed by a potting resin in a lump.

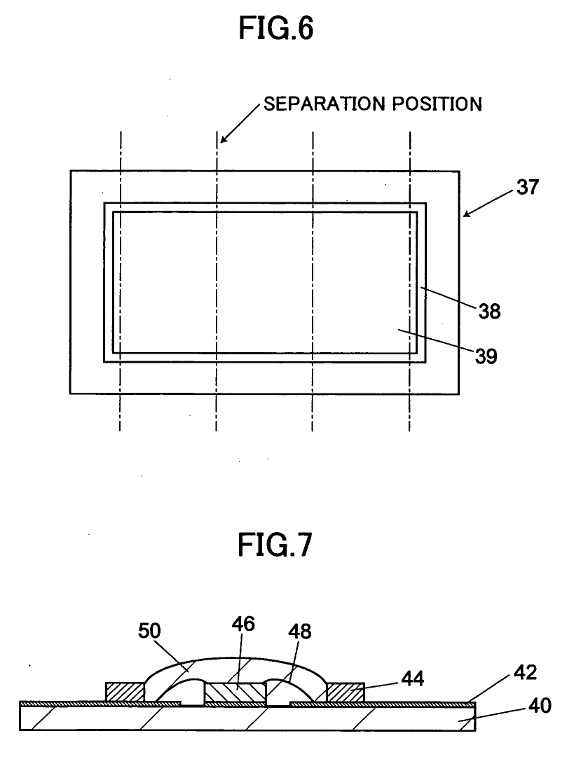

FIG. 6 is a view illustrating a modification of the present invention.

As illustrated in FIG. 6, in an electronic unit panel 37, a resin-outflow-prevention dam 38 is formed on plural printed circuit boards and is shared by the printed circuit boards, and sealing with potting resin on all the printed circuit boards is executed by utilizing the resin-outflow-prevention dam 38. After being sealed with resin, the plural electronic units mounted on the printed circuit boards are separated along the dotted-dashed lines in FIG. 6, thus becoming separate electronic units.

According to this example, when a resin-outflow-prevention dam 38 is formed to be shared by the printed circuit boards, and sealing with resin is executed at once, plural electronic units can be formed at the same time with a small number of fabrication steps compared to the case in which dams are formed separated on different printed circuit boards and sealing with resin is executed separately. Therefore, the efficiency of fabricating electronic units can be improved.

According to the present invention, the outer side surface and the upper surface of the resin-outflow-prevention dam subtend an acute angle. Therefore, due to surface tension at the angular portion of the acute angle subtended by the outer side surface and the upper surface of the resin-outflow-prevention dam, the sealing resin can hardly drop from the outer side surface; thus, it is possible to prevent the sealing resin from running out of the sealing region.

In addition, because the resin-outflow-prevention dam may have a quadrilateral cross section, for example, the resin-outflow-prevention dam may have approximately an inverse trapezoidal cross section, and the width of the upper surface may be greater than the width of the lower surface. Due to the surface tension at the angular portion of the acute angle subtended by the outer side surface and the upper surface of the resin-outflow-prevention dam, the sealing resin can hardly drop from the outer side surface, and thus, it is possible to prevent the sealing resin from running out of the sealing region.

In addition, because an insulating material layer may be formed on the printed circuit board and may at least have an opening in a region where the electrode is formed, and the resin-outflow-prevention dam may be formed on the insulating material layer, due to the surface tension at the angular portion of the acute angle subtended by the outer side surface and the upper surface of the resin-outflow-prevention dam, the sealing resin can hardly drop from the outer side surface. Thus, it is possible to prevent the sealing resin from running out of the sealing region.

In addition, because an insulating material layer may be formed on the printed circuit board and may at least have an opening in a region where the electrode is formed, and the resin-outflow-prevention dam may be formed from the insulating material, the resin-outflow-prevention dam may be formed by removing unnecessary portions of the insulating material layer. Hence, additional steps are not needed to form the resin-outflow-prevention dam, making it easy to fabricate the resin-outflow-prevention dam.

In addition, in the electronic unit of the present invention, an electronic part is connected to a conductive pattern through an electrode, and resin is applied in a resin-sealing region to cover the upper surface of the resin-outflow-prevention dam. Therefore, in the angular portion subtended by the outer side surface and the upper surface of the resin-outflow-prevention dam, the resin projects upward due to the surface tension, and this results in a sufficient height of the resin.

In addition, the material layer is etched selectively by dry etching with the etching mask pattern as a mask to remove the material layer selectively, and then the material layer is over-etched, thereby obtaining the resin-outflow-prevention dam having approximately an inverse trapezoidal cross section.

In addition, a light-shielding mask is arranged on the photo-sensitive material layer in an area where the resin-outflow-prevention dam is to be formed, and the photo-sensitive material layer is over-exposed by using the light-shielding mask. Then the photosensitive material layer is developed, resulting in the resin-outflow-prevention dam having approximately an inverse trapezoidal cross section.

While the present invention is described above with reference to specific embodiments chosen for purpose of illustration, it should be apparent that the invention is not limited to these embodiments, but numerous modifications could be made thereto by those skilled in the art without departing from the basic concept and scope of the invention.

For example, in the above examples, it is described that the resin-outflow-prevention dams 10, 30, and 38 are formed by using the solder resist. But the present invention is not limited to this; instead, for example, the resin-outflow-prevention dams may be formed from a silicon resin.

When fabricating a printed circuit board and an electronic unit, if it is desired to reduce the number of fabrication steps, it is preferable to use the solder resist or other insulating materials to form the resin-outflow-prevention dam, as this reduces additional steps for forming the resin-outflow-prevention dam.

This patent application is based on Japanese Priority Patent Application No. 2004-283393 filed on Sep. 29, 2004, the entire contents of which are hereby incorporated by reference.

What is claimed is:

1. A printed circuit board, comprising:
a conductive pattern formed on an insulating substrate;
an electrode for connecting an electronic part to the conductive pattern; and
a stripe-like resin-outflow-prevention dam arranged in a periphery of a resin-sealing region covering the electronic part;
wherein an outer side surface of the resin-outflow-prevention dam and an upper surface of the resin-outflow-prevention dam subtend an acute angle.

2. The printed circuit board as claimed in claim 1, wherein
the resin-outflow-prevention dam has a quadrilateral cross section; and
a width of the upper surface of the resin-outflow-prevention dam is greater than a width of a lower surface of the resin-outflow-prevention dam.

3. The printed circuit board as claimed in claim 2, wherein the resin-outflow-prevention dam has approximately an inverse trapezoidal cross section.

4. The printed circuit board as claimed in claim 1, wherein
an insulating material layer is formed on the printed circuit board and at least has an opening in a region where the electrode is formed, and
the resin-outflow-prevention dam is formed on the insulating material layer.

5. The printed circuit board as claimed in claim 1, wherein
an insulating material layer is formed on the printed circuit board and at least has an opening in a region where the electrode is formed, and
the resin-outflow-prevention dam is formed from the insulating material.

6. An electronic unit, comprising:
a printed circuit board having a conductive pattern formed on an insulating substrate, an electrode, and a stripe-like resin-outflow-prevention dam; and
an electronic part that is connected to the conductive pattern through the electrode to mount the electronic part on the printed circuit board;
wherein
the resin-outflow-prevention dam is arranged in a periphery of a resin-sealing region covering the electronic part, and
a resin for sealing is applied in the resin-sealing region to cover the upper surface of the resin-outflow-prevention dam.

7. A method of producing a printed circuit board including a conductive pattern formed on an insulating substrate, and an electrode for connecting an electronic part to the conductive pattern; and a resin-outflow-prevention dam arranged in a periphery of a resin-sealing region covering the electronic part,
said method comprising the steps:
depositing a material layer on the insulating substrate for forming the resin-outflow-prevention dam;
forming an etching mask pattern on the material layer in an area where the resin-outflow-prevention dam is to be formed;
etching the material layer selectively by dry etching with the etching mask pattern as a mask to selectively remove the material layer; and
over-etching the material layer to form the resin-outflow-prevention dam having approximately an inverse trapezoidal cross section.

8. A method of producing a printed circuit board including a conductive pattern formed on an insulating substrate, and an electrode for connecting an electronic part to the conductive pattern; and a resin-outflow-prevention dam arranged in a periphery of a resin-sealing region covering the electronic part,
said method comprising the steps:
depositing a positive photosensitive material layer on the insulating substrate for forming the resin-outflow-prevention dam;
arranging a light-shielding mask on the photosensitive material layer in an area where the resin-outflow-prevention dam is to be formed;
over-exposing the photo-sensitive material layer by using the light-shielding mask; and
developing the photosensitive material layer to form the resin-outflow-prevention dam having approximately an inverse trapezoidal cross section.
